(19) United States
(12) Patent Application Publication
(10) Pub. No.: US 2003/0112023 A1
(43) Pub. Date: Jun. 19, 2003

(54) Mechanical-electrical transducer

(76) Inventors: Heiko Jausel, Neustadt an der Weinstrasse (DE); Erich Mattmann, Heidesheim (DE); Uwe Neumann-Henneberg, Frankfurt (DE)

Correspondence Address: Kevin R. Spivak, Morrison & Foerster LLP, Suite 300, 1650 Tysons Boulevard, McLean, VA, 22102, US

(21) Appl. No.: 10/293,930

(22) Filed: Nov. 14, 2002

(30) Foreign Application Priority Data
Nov. 15, 2001 (DE) 10156160.1

(51) Int. Cl. G01R 29/22

(52) U.S. Cl. 324/727

(57) ABSTRACT

The invention relates to a mechanical-electrical transducer having a bridge circuit formed on an insulation layer through an electrical interconnection of expansion-sensitive thick-film resistors by means of conductor tracks. The insulation layer is arranged directly on a metallic component that is to be mechanically loaded, and being intimately connected to said component by means of a thermal process. In this case, in the event of mechanical stressing of the component, an electrical signal corresponding to the expansion of the thick-film resistors can be tapped off. In order that the mechanical-electrical transducer exhibits a small electrical offset in the output signal in the event of mechanical loading, the metallic component to be loaded comprises a thermally post-hardening metal or a thermally post-hardening metal alloy.

### CLAIM FOR PRIORITY

This application claims priority to Application No. 10156160.1 which was filed in the German language on Nov. 15, 2001.

### TECHNICAL FIELD OF THE INVENTION

The invention relates to a mechanical-electrical transducer, and in particular, to a bridge circuit formed on an insulation layer through an electrical interconnection of expansion-sensitive thick-film resistors by means of conductor tracks.

### BACKGROUND OF THE INVENTION

The German patent application DE 198 14 261 A1 discloses a generic mechanical-electrical transducer. In the case of this transducer, the expansion-sensitive thick-film resistors are arranged on an insulation layer which is in turn arranged directly on a metal shaft formed as carrier element. In this case, the shaft is exposed to mechanical loading in the form of a torsion, the resultant area expansion being tapped off by the resistor that is arranged on the shaft without a mechanical intermediate carrier. In this case, the insulation layer is applied in the form of a thick-film paste on the shaft using printing technology and is intimately connected to the shaft after a thermal treatment. Such sensors exhibit an offset in the output signal, which offset must be corrected by a complicated electronic circuit in order to obtain a precise signal corresponding to the force acting on the carrier.

### SUMMARY OF THE INVENTION

The invention relates to a mechanical-electrical transducer having a bridge circuit formed on an insulation layer through an electrical interconnection of expansion-sensitive thick-film resistors by means of conductor tracks. The insulation layer being arranged directly on a metallic component that is to be mechanically loaded, and being intimately connected to the component by means of a thermal process. In this case, in the event of mechanical stressing of the component, an electrical signal corresponding to the expansion of the thick-film resistors can be tapped off.

The invention specifies a mechanical-electrical transducer which exhibits a small electrical offset in the output signal in the event of mechanical loading.

According to the invention, a metallic component to be loaded comprises a thermally post-hardening metal or a thermally post-hardening metal alloy.

The invention has the advantage, in one embodiment, that the thermally post-hardening metal or the thermally post-hardening metal alloy which is intended to be used for the sensor experiences, during thermal processes, a material structure alteration which decisively improves its elasticity, hardness, mechanical expansion limit and endurance strength. Plastic deformations of the metal or the metal alloy are avoided in the event of intended mechanical loading. The improved elasticity of the metallic component after thermal hardening forms the basis of a smaller bending hysteresis, which leads to a decisive reduction of the offset in the output signal of the sensor. The increased hardness and expansion limit of the metallic component in the thermal processes enables the use of thinner and thus lighter and more cost-effective metal carriers.

Owing to the increased hardness, the use of steels with a thickness of about less than 6 mm becomes possible. These steels are available as rolled scripts, which results in a significant simplification of the production process and an improvement in the quality of the metal carriers produced.

In embodiment of the invention, the thermally post-hardening metal or the thermally post-hardening metal alloy can be hardened at a temperature of about 600° C. to 1100° C. Advantageously in this case, the metal component is hardened under the same thermal process parameters which are also used for the sintering of the thick films, which means that additional process steps can be dispensed with.

In still another embodiment, the insulation layer is applied to a thermally post-hardening metal that is already thermally hardened or a thermally post-hardening metal alloy that is already thermally hardened. The thermally post-hardening metal or the thermally post-hardening metal alloy is pre-hardened in air, which results in oxidation of the metal surface or alloy surface and allows a better intimate connection of the insulation layer to the metal surface or alloy surface. Primarily the aluminum and chromium oxides produced in this case on the metal surface or alloy surface ensure the permanent chemical bonding to the insulation layer containing silicon oxides.

In other embodiments, the insulation layer is alternatively formed as a paste-like glass frit which is bonded by oxide bridges to the metallic component via its oxide layer, or is formed as a film containing a glass frit which is bonded by oxide bridges to the metallic component via its oxide layer The paste-like insulation layer is applied to the metal surfaces using screen printing technology and is sintered in the known thermal process. The silicon oxide constituents of the glass frit forming an intimate connection in the form of oxide bridges to the surface oxide layer of the metallic component. This ensures a long-lived connection—commensurate with the mechanical stresses—between the first thick film and the metallic component.

If the insulation layer is formed as a film, it is possible to apply other thick films to the film, after which the film carrying the thick films is placed onto the metallic component and the system comprising insulation layer, resistance layer and conductor track layer is sintered in a thermal process. Under the influence of the high temperature, the resin constituents of the film outgas virtually completely and the glass constituents remain, which bond to the oxidized metal surface in the known manner. The desired material structure change in the metallic component also takes place during this thermal operation.

In still another embodiment, the unhardened, thermally post-hardening metal or the thermally post-hardening metal alloy is low temperature impact resistant. This ensures good mechanical processability of the metallic blank before the thermal treatments. In the case of metals or metal alloys that are low temperature impact resistant, few if any microcracks form in the material during mechanical shaping methods that are customary on an industrial scale, such as cold stamping, for example, which results in a higher quality of the metallic component after the mechanical processing.

In another embodiment, the component to be loaded has, on its surface, at least one recess which, in the event of mechanical stressing of the component to be loaded, generates an unequal ratio—in terms of magnitude—of the two main expansions, the thick-film resistors being arranged in the radial direction with respect to the at least one recess. The unequal main expansions—in terms of magnitude—of the metal carrier that are generated in the event of mechanical stressing of the sensor cause unequal area expansions in the thick-film resistors, which results in an unequal change in resistance and from which is obtained a well-measurable and sufficiently large signal of the measuring bridge connected up from the resistors.

In yet another embodiment, at least one recess is formed as an elongated hole, circle or semicircle, the thick-film resistors being arranged in the vicinity of the radial regions of the at least one recess. As a result of this, a particularly pronounced unequal area expansion occurs in the thick-film resistors, which results in a particularly high measurement signal which can be processed directly by the downstream electronics without complicated amplification. Such mechanical-electrical transducers can be used for example as torsion sensors in electrically assisted motor vehicle steering systems.

### BRIEF DESCRIPTION OF THE DRAWINGS

The invention permits numerous embodiments. The embodiments will be explained with reference to the figures illustrated in the drawings.

FIG. 1 shows a plan view of a mechanically-electrical transducer according to the invention.

FIG. 2 shows a mechanical-electrical transducer according to the invention in section.

FIG. 3 shows a mechanical-electrical transducer according to the invention with a multilayer structure in section.

### DETAILED DESCRIPTION OF THE INVENTION

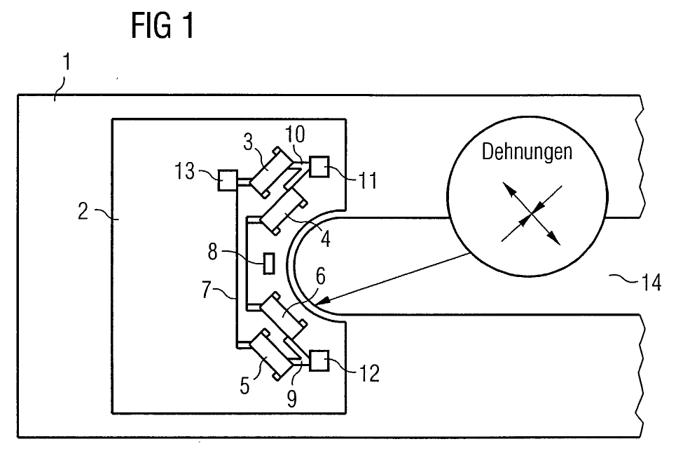

FIG. 1 illustrates a mechanical-electrical transducer according to the invention for application in steering assistance systems in motor vehicles. An insulation layer 2 is arranged on a shaft 1 which is to be loaded torsionally and which comprises a thermally post-hardening metal or a thermally post-hardening metal alloy and is of parallel-epipedal design. A resistor bridge comprising expansion-sensitive thick-film resistors 3 to 6 is arranged on the insulation layer 2. The thick-film resistors 3 to 6 are electrically connected to form a resistance measuring bridge by conductor tracks 7 to 10. Contact points 11 to 13 may be provided for tapping off the electrical signals of the resistance measuring bridge and for forwarding them to an electronic evaluation circuit. As an alternative, via further conductor tracks, the signals can also be fed directly to an electronic circuit arranged on the thick film, which electronic circuit is not illustrated in detail here. In order to obtain a maximum area expansion in the thick-film resistors 3 to 6, continuous recesses 14 are introduced into the metallic component. In this case, a recess 14 in the form of an elongated hole is illustrated, but round, half-round, and at least triangular recesses can advantageously be used.

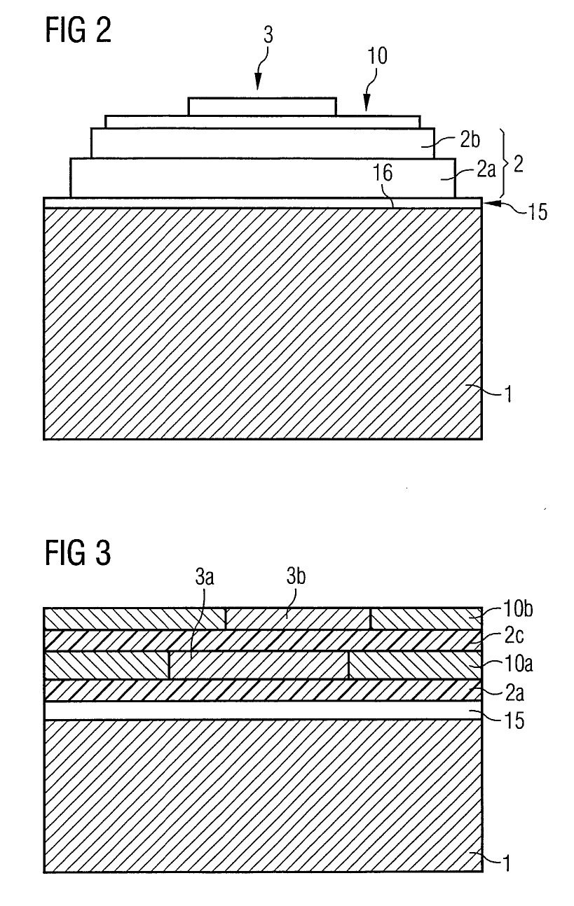

FIG. 2 shows a section through a mechanical-electrical transducer according to the invention. A thermally post-hardening metal or a thermally post-hardening metal alloy 1 is covered with an oxidized surface 15. An insulation layer 2 comprising two layers 2a, 2b lying one above the other is arranged on the oxidized metal surface 15. The insulation layer 2 may be formed as a paste-like thick film or as a film. A thick-film resistor 3 and a conductor track 10 are applied to the insulation layer 2.

The mechanical-electrical transducer described is produced as follows. A metallic material 1 is processed mechanically in order to bring the raw material to the form required for the sensor. The parallel-epipedal configuration and also the round, half-round, elongated-hole-shaped or at least triangular recesses 14 are impressed on the blank. In this case, industrial scale processing methods such as cold stamping, for example, are advantageous because they can be carried out cost-effectively, rapidly and for producing large numbers. With the use of thermally post-hardening metals or metal alloys for the production of the sensors, the mechanical processing takes place largely free from microcracks, since the thermally post-hardening metals or metal alloys are low temperature impact resistant before the first thermal process step.

The mechanical processing of the metallic workpiece is followed by a first thermal process step, which is necessary for surface refinement. In this case, the workpiece is heated from room temperature to about 750°-900° C. in approximately 15-25 min, then left under the influence of this temperature for approximately 5-15 min and then cooled to room temperature over a period of 15-25 min. This temperature profile is also maintained in subsequent thermal processes. Since this thermal process step is conducted in air, the surface 16 of the metallic component 1 is altered oxidatively in the first thermal process. Subsequently, an insulation layer 2a in the form of a paste is applied and sintered in a known manner. The oxide layer 15 on the surface 16 of the metallic component 1 ensures an intimate connection between the metal and the sintered-on insulation layer 2a, since oxide bridges are formed from the metal oxide 15 of the component 1 to be loaded to the oxides in the insulation layer to be applied. In order to increase the electrical breakdown strength, a further insulation layer 2b is applied and sintered.

The application of a paste from which the resistor 3 is formed and of a paste from which the conductor track 10 is formed and renewed sintering in the temperature scheme mentioned then takes place. Within these thermal processes, which are necessary anyway, the thermally post-hardening metallic carrier 1 undergoes a material structure change which advantageously affects its mechanical properties such as hardness, expansion limit, long-term strength and elasticity.

As an alternative to the insulation paste, the insulation layer 2 can also be realized as a film layer. This dielectric film layer comprises synthetic resins with an admixed glass frit. Conductor tracks 7 to 10 and resistors 3 to 6, as illustrated in FIG. 1, are applied on the film-like dielectric 2 using screen printing technology. Afterward, the film-like dielectric 2 is placed onto the metallic component 1 with the printed-on structure outward and sintered in a thermal process. The thermal process conditions correspond to those during the already described sintering of the pastes. Under the influence of the high temperature, the plastics escape from the film-like dielectric 2 and the glass constituents combine with the previously oxidized metal surface 15 to form the oxide bridges already mentioned. The pastes present on the film-like dielectric 2 are likewise sintered in this step. During this thermal process step, too, the metallic component 1 undergoes the desired material structure change, which leads to the already described improvements in the mechanical and electrical properties of the mechanical-electrical transducer. This technique has the advantage of requiring a thermal process for oxidation of the metal surface 15 and another thermal step for sintering the system comprising insulation film 2, thick-film resistors 3 to 6 and thick-film conductor tracks 7 to 10.

Repeated application of the above-described steps makes it possible to realize a complex multilayer architecture, as illustrated in FIG. 3, on the metallic component 1. In this case, an oxide layer 15 is present on the metal carrier 1 and is connected to the first insulation layer 2a, on which the resistor 3a and conductor track 10a are applied using thick-film technology. An additional insulation layer 2c is applied above the first resistor 3a and the first conductor track 10a, which layer may be formed as a paste-like thick film or as a film. An additional resistor 3b and an additional conductor track 10b are then applied to the insulation layer 2c. The layer construction described can be effected until technological or functional limits are reached.

What is claimed is:

1. A mechanical-electrical transducer, comprising:
a bridge circuit formed on an insulation layer through an electrical interconnection of expansion-sensitive thick-film resistors by means of conductor tracks, the insulation layer arranged directly on a metallic component that is configured to be mechanically loaded, and connected to the component by means of a thermal process, wherein
when the component is mechanically stressed, an electrical signal corresponding to the expansion of the thick-film resistors is tapped off, such that the metallic component to be loaded comprises a thermally post-hardening metal or a thermally post-hardening metal alloy.

2. The mechanical-electrical transducer as claimed in claim 1, wherein the thermally post-hardening metal or the thermally post-hardening metal alloy is hardened at a temperature of about 600° C. to 1100° C.

3. The mechanical-electrical transducer as claimed in claim 1, wherein the insulation layer is applied to a thermally post-hardening metal that is already thermally hardened or a thermally post-hardening metal alloy that is already thermally hardened.

4. The mechanical-electrical transducer as claimed in claim 3, wherein the insulation layer is formed as a paste-like glass frit which is bonded by oxide bridges to the metallic component via an oxide layer.

5. The mechanical-electrical transducer as claimed in claim 3, wherein the insulation layer is formed as a film containing a glass frit which is bonded by oxide bridges to the metallic component via an oxide layer.

6. The mechanical-electrical transducer as claimed in claim 1, wherein the unhardened, thermally post-hardening metal or the thermally post-hardening metal alloy is low temperature impact resistant.

7. The mechanical-electrical transducer as claimed in claim 1, wherein the component configured to be loaded has at least one recess on its surface, and in the event of mechanical stressing of the component configured to be loaded, generates an unequal ratio of two main expansions, the thick-film resistors arranged in a radial direction with respect to the at least one recess.

8. The mechanical-electrical transducer as claimed in claim 7, wherein the at least one recess is formed as an elongated hole, circle or semicircle, the thick-film resistors arranged in vicinity of radial regions of the at least one recess.

9. The mechanical-electrical transducer as claimed in claim 2, wherein the insulation layer is applied to a thermally post-hardening metal that is already thermally hardened or a thermally post-hardening metal alloy that is already thermally hardened.
